(19) United States
(12) Patent Application Publication
(10) Pub. No.: US 2026/0223748 A1
(43) Pub. Date: Jul. 30, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Susumu OBATA, Yokohama (JP); Kazuhito HIGUCHI, Yokohama (JP); Tatsuya OHGURO, Yokohama (JP); Takenori YASUZUMI, Yokohama (JP); Hiroki KAWAKAMI, Kanazawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/440,960

(22) Filed: Jan. 6, 2026

(30) Foreign Application Priority Data
Jan. 27, 2025 (JP) 2025-011580

(51) Int. Cl. H10W 90/28; H10W 90/00; H10D 80/30; H10W 72/00

(52) U.S. Cl. CPC H10W 90/28; H10W 90/736; H10W 90/756; H10W 90/766; H10D 80/30; H10W 72/871; H10W 72/884; H10W 72/886

(57) ABSTRACT

According to one embodiment, a semiconductor device includes: a package substrate including first and second terminals; a first chip on the first terminal and including a switch; a connector extending from a front surface of the first chip to the second terminal; and a second chip on the connector above the first chip and including a resistor and a capacitor in a semiconductor substrate. The first chip includes a first electrode on the front surface of the first chip and a second electrode on a back surface of the first chip. The second chip includes a third electrode and a fourth electrode. The first electrode is coupled to the second terminal, the second electrode is coupled to the first terminal, the third electrode is coupled to the first terminal, and the fourth electrode is coupled to the second terminal.

### CROSS-REFERENCE TO RELATED APPLICATIONS

This application is based upon and claims the benefit of priority from Japanese Patent Application No. 2025-011580, filed January 27, 2025, the entire contents of which are incorporated herein by reference.

### FIELD

Embodiments described herein relate generally to a semiconductor device.

### BACKGROUND

Snubber circuits are used in power modules to stabilize the operation of switching elements.

### BRIEF DESCRIPTION OF THE DRAWINGS

FIG. 1 is a circuit diagram showing a configuration example of a semiconductor device according to the first embodiment.

FIG. 2 is a bird's-eye view showing a structural example of the semiconductor device according to the first embodiment.

FIG. 3 is a plan view showing a structural example of the semiconductor device according to the first embodiment.

FIG. 4 is a cross-sectional view showing a structural example of the semiconductor device according to the first embodiment.

FIG. 5 is a cross-sectional view showing a structural example of the semiconductor device according to the first embodiment.

FIG. 6 is a flowchart showing a manufacturing method of the semiconductor device according to the first embodiment.

FIG. 7 is a graph showing the characteristics of the semiconductor device according to the first embodiment.

FIG. 8 is a graph showing the characteristics of the semiconductor device according to the first embodiment.

FIG. 9 is a plan view showing a structural example of a semiconductor device according to the second embodiment.

FIG. 10 is a cross-sectional view showing a structural example of the semiconductor device according to the second embodiment.

FIG. 11 is a circuit diagram showing a configuration example of the semiconductor device according to the second embodiment.

FIG. 12 is a plan view showing a structural example of a semiconductor device according to the third embodiment.

FIG. 13 is a cross-sectional view showing a structural example of the semiconductor device according to the third embodiment.

FIG. 14 is a cross-sectional view showing a structural example of the semiconductor device according to the third embodiment.

FIG. 15 is a plan view showing an structural example of a semiconductor device according to the fourth embodiment.

FIG. 16 is a cross-sectional view showing a structural example of the semiconductor device according to the fourth embodiment.

FIG. 17 is a cross-sectional view showing a structural example of the semiconductor device according to the fourth embodiment.

FIG. 18 is a circuit diagram showing a configuration example of a semiconductor device according to the fifth embodiment.

FIG. 19 is a cross-sectional view showing a structural example of the semiconductor device according to the fifth embodiment.

### DETAILED DESCRIPTION

In general, according to one embodiment, a semiconductor device includes: a package substrate including a first lead terminal and a second lead terminal; a first semiconductor chip provided on the first lead terminal and including a switching element; a connector extending from a front surface of the first semiconductor chip to the second lead terminal; and a second semiconductor chip provided on the connector above the first semiconductor chip and including a resistor portion and a first capacitor portion provided in a semiconductor substrate, wherein the first semiconductor chip includes a first electrode provided on the front surface of the first semiconductor chip and a second electrode provided on a back surface of the first semiconductor chip, the second semiconductor chip includes a third electrode and a fourth electrode, the first electrode is electrically coupled to the second lead terminal, the second electrode is electrically coupled to the first lead terminal, the third electrode is electrically coupled to the first lead terminal, and the fourth electrode is electrically coupled to the second lead terminal.

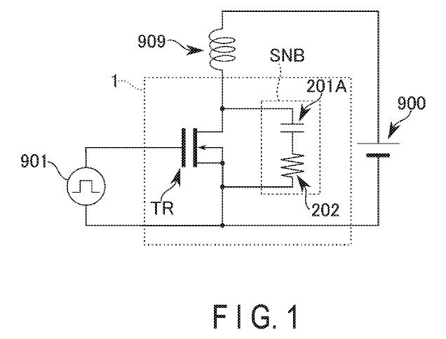

Semiconductor devices according to embodiments and manufacturing methods thereof will be described with reference to FIGS. 1 to 19. In the description below, elements having the same functions and configurations will be denoted by the same reference symbols. In the embodiments described below, where constituent elements denoted by reference symbols to which numbers/letters are attached at the end for discrimination (e.g., circuits, interconnects, various voltages and signals) do not have to be discriminated from each other, reference symbols without the numbers/letters at the end will be used.

### EMBODIMENTS

### First Embodiment

A semiconductor device according to the first embodiment and a manufacturing method thereof will be described with reference to FIGS. 1 to 8.

### Configuration Example

A configuration example of the semiconductor device of the present embodiment will be described with reference to FIGS. 1 to 5.

FIG. 1 is a circuit diagram showing a circuit configuration of the semiconductor device 1 according to the first embodiment.

As shown in FIG. 1, the semiconductor device 1 of the present embodiment is a power device (power module) including a transistor TR and a snubber circuit SNB.

The transistor TR is a switching element. The transistor TR is a field-effect transistor TR having a MOS (Metal-Oxide-Semiconductor) structure. For example, the transistor TR is an N-channel MOSFET. The transistor TR includes a semiconductor such as silicon (Si), silicon carbide (SiC), or gallium nitride (GaN). The transistor TR is a low-breakdown voltage MOSFET (with a breakdown voltage of about 12V to 300V) and is driven, for example, at an operating voltage of 6V or higher and 300V or lower. In the description below, the transistor TR will also be referred to as an LVMOS.

The transistor TR may be a P-channel field-effect transistor or an IGBT (Insulated Gate Bipolar Transistor).

The transistor TR is coupled to a DC power supply 900. One end (e.g., drain) of the current path of the transistor TR is coupled to the high-potential terminal of the DC power supply 900 via an inductor 909. The other end (e.g., source) of the current path of the transistor TR is coupled to the low-potential terminal of the DC power supply 900. The control terminal (gate) of the transistor TR is coupled to a signal source (e.g., a driver circuit) 901. The transistor TR turns on or off in response to a pulse signal (a control signal, a gate voltage) supplied from the signal source 901. Note that the inductor 909 may be a device for adjusting the operating characteristics of the transistor TR, or may be a parasitic component included in the wiring between the transistor TR and the DC power supply 900.

The snubber circuit SNB suppresses surge voltages generated during switching operations of the transistor TR. The snubber circuit SNB includes a capacitor (a capacitance element, a condenser) 201A and a resistor (resistance element) 202.

The snubber circuit SNB is coupled in parallel with the current path of the transistor TR. One end of the capacitor 201A is coupled to one end of the current path of the transistor TR. The other end of the capacitor 201A is coupled to one end of the resistor 202. The other end of the resistor 202 is coupled to the other end of the current path of the transistor TR. Depending on the circuit configuration of the snubber circuit SNB, one end of the resistor 202 may be coupled to one end of the current path of the transistor TR, and the other end of the resistor 202 may be coupled to one end of the capacitor 201A, and the other end of the capacitor 201A may be coupled to the other end of the current path of the transistor TR.

For example, with the configuration shown in FIG. 1, the semiconductor device 1 of the present embodiment functions as a switching device for power conversion in a device (e.g., an inverter or converter) external to the semiconductor device 1.

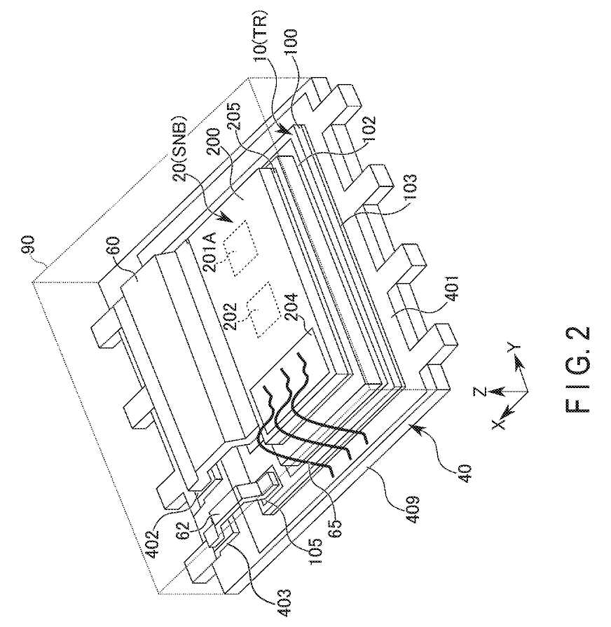

FIGS. 2 to 5 are diagrams showing structural examples of the semiconductor device 1 of the present embodiment.

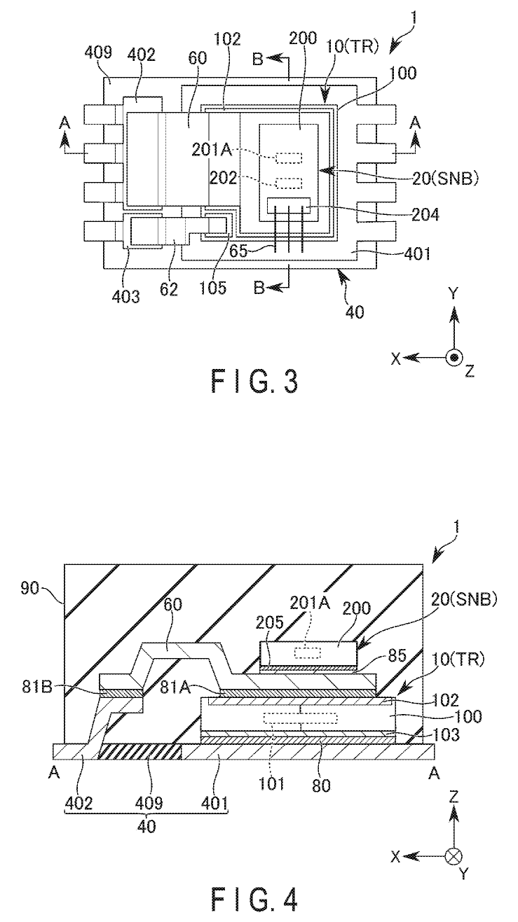

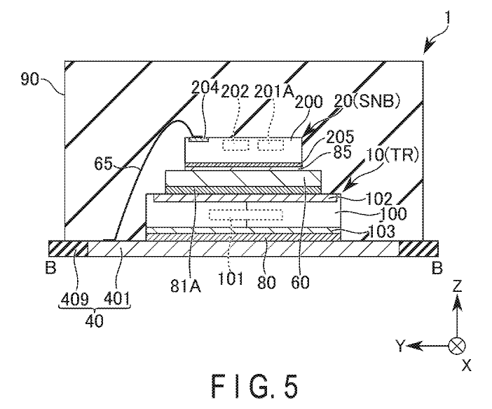

FIG. 2 is a bird's-eye view showing a structural example of the semiconductor device 1 of the present embodiment. FIG. 3 is a top view showing an example of the planar structure of the semiconductor device 1 of the present embodiment. FIG. 4 is a cross-sectional view taken along line A-A in FIG. 3 and shows an example of the cross-sectional structure of the semiconductor device 1 of the present embodiment. FIG. 5 is a cross-sectional view taken along line B-B in FIG. 3 and shows an example of the cross-sectional structure of the semiconductor device 1 of the present embodiment.

In the description below, a direction parallel to a certain plane will be referred to as an X-direction, and a direction parallel to the certain plane and intersecting the X-direction will be referred to as a Y-direction. The direction perpendicular to the plane defined by the X-direction and the Y-direction will be referred to as a Z-direction.

As shown in FIGS. 2 to 5, in the semiconductor device 1 of the present embodiment, the semiconductor chip 20 of the snubber circuit SNB is stacked on the semiconductor chip 10 of the transistor TR. The two stacked semiconductor chips 10 and 20 are provided on a package substrate 40. The two semiconductor chips 10 and 20 are covered by a sealing member 90 on the package substrate 40. The semiconductor chips 10 and 20 are coupled to terminals 401, 402 and 403 of the package substrate 40. Thus, the semiconductor chips 10 and 20 are electrically coupled to devices external to the semiconductor device 1.

The package substrate 40 is a lead frame 40. The lead frame 40 includes lead terminals 401, 402 and 403, and an insulator 409.

Each of the lead terminals 401, 402, and 403 is a metal plate containing (including) copper (Cu). The lead terminals 401, 402 and 403 are spaced apart from one another. The lead terminals 401, 402 and 403 are provided within the insulator 409. The lead terminals 401, 402 and 403 are electrically insulated from one another by the insulator 409.

For example, the lead terminal 401 has a flat plate shape. For example, each of the lead terminals 402 and 403 is bent upward in the Z-direction at one end so as to be positioned above the surface of the lead terminal 401. The positions of the one-end portions of the lead terminals 402 and 403, as viewed in the Z-direction, are substantially aligned with the position of the front surface of the semiconductor chip 10 in the Z-direction. The lead terminal 402 includes a portion inclined with respect to the X-Y plane between one X-direction end of the lead terminal 402 and the other X-direction end of the lead terminal 402. One X-direction end of the lead terminal 402 is positioned higher in the Z direction than the other X-direction end of the lead terminal 402. The lead terminal 403 includes a portion inclined with respect to the X-Y plane between one X-direction end of the lead terminal 403 and the other X-direction end of the lead terminal 403. One X-direction end of the lead terminal 403 is positioned higher in the Z direction than the other X-direction end of the lead terminal 403.

The lead terminal 401 is coupled to an electrode 103 at one end of the current path of the transistor TR via a conductor 80. The lead terminal 402 is electrically coupled to the electrode 102 at the other end of the current path of the transistor TR via a connector 60 described below. The lead terminal 403 is electrically coupled to an electrode 105 of the control terminal of the transistor TR via a connector 62 described below.

The package substrate 40 may have various structures, such as a small outline package (SOP) structure or a quad flat package (QFP) structure.

The transistor TR is formed in the semiconductor chip 10. In the description below, the semiconductor chip 10 of the transistor TR will be referred to as a transistor chip 10.

The transistor chip 10 is provided on the lead frame 40. More specifically, for example, the transistor chip 10 is provided on the lead terminal 401 of the lead frame 40.

The transistor chip 10 includes a substrate 100, an element portion 101, and electrodes 102, 103 and 105.

The substrate 100 is one of the following: a silicon (Si) substrate, a silicon carbide (SiC) substrate, a gallium nitride (GaN) substrate, a zinc oxide (ZnO) substrate, a gallium oxide (Ga₂O₃) substrate, an aluminum nitride (AlN) substrate, or a diamond substrate (carbon (C) substrate).

The element portion 101 is provided in and/or on the substrate 100. The element portion 101 includes various semiconductor layers and conductive layers as components of the transistor TR. Each of the semiconductor layers and conductive layers of the element portion 101 is electrically coupled to the corresponding one of the electrodes 102, 103 and 105 via contact plugs (not shown) and interconnects (not shown).

The electrode 102 is provided within the front surface of the substrate 100. The electrode 102 is, for example, a source electrode 102 of the transistor TR. The electrode 103 is provided within the back surface of the substrate 100. The electrode 103 faces the electrode 102 in a direction perpendicular to the front surface of the substrate 100 (the Z direction). The electrode 103 is, for example, a drain electrode 103 of the transistor TR. The electrode 105 is provided within the front surface of the substrate 100. The electrode 105 is adjacent to the electrode 102 in directions parallel to the front surface of the substrate 100 (the X and Y directions). The electrode 105 is, for example, a gate electrode 105 of the transistor TR. Thus, in the case where the transistor TR is a vertical transistor, the source electrode 102 of the transistor TR overlaps the drain electrode 103 of the transistor TR in the Z direction.

The electrode 102 is electrically coupled to the connector 60 via a conductor 81A such as solder or conductive paste. The electrode 103 is electrically coupled to the lead terminal 401 via a conductor 80 such as solder or conductive paste. The electrode 105 is electrically coupled to the connector 62 via a conductor (not shown) such as solder or conductive paste.

The connector 60 is a metal plate containing copper (Cu). The connector 60 is provided on the lead terminal 402 of the lead frame 40 and on the front surface of the transistor chip 10. The connector 60 extends in the X-direction so as to span, for example, between the lead terminal 402 and the transistor chip 10. The connector 60 has, for example, a bridge shape. The central portion of the connector 60 is positioned higher in the Z-direction than both X-direction ends of the connector 60. One X-direction end of the connector 60 is electrically coupled to one X-direction end of the lead terminal 402 via a conductor 81B such as solder or conductive paste. The other X-direction end of the connector 60 is electrically coupled to the electrode 102 of the transistor chip 10 via the conductor 81A. The conductor 81A is provided between the connector 60 and the electrode 102. The conductor 81B is provided between the connector 60 and the lead terminal 402.

The connector 62 is a metal plate containing copper. The connector 62 is provided on the lead terminal 403 of the lead frame 40 and on the front surface of the transistor chip 10. The connector 62 extends in the X-direction so as to span between the lead terminal 403 and the transistor chip 10. The connector 62 has, for example, a bridge shape. The central portion of the connector 62 is positioned higher in the Z-direction than both X-direction ends of the connector 62. One X-direction end of the connector 62 is electrically coupled to one X-direction end of the lead terminal 403 via a conductor (not shown). The other X-direction end of the connector 62 is electrically coupled to the electrode 105 of the transistor chip 10 via a conductor (not shown).

One end (electrode 102) of the current path of the transistor TR is coupled to the lead terminal 402 via the connector 60. The other end (electrode 103) of the current path of the transistor TR is electrically coupled to the lead terminal 401. The control terminal of the transistor TR is coupled to the lead terminal 403 via the connector 62.

The package substrate 40 may have a clip structure including a member (hereinafter referred to as a clip) in which the connector 60 and the lead terminals 402 are integrated, and another member (clip) in which the connector 62 and the lead terminals 403 are integrated. In the case where the transistor chip 10 is mounted on a package substrate 40 of the clip structure, the transistor chip 10 is sandwiched between the lead terminal 401 and two clips respectively corresponding to the lead terminals 402 and 403. In this case, the clip corresponding to the lead terminal 402 is electrically coupled to the electrode 102 of the transistor chip 10 without the conductor 81A being provided on the electrode 102. On the other hand, the clip corresponding to the lead terminal 403 is electrically coupled to the electrode 105 of the transistor chip 10 without an intervening conductor.

The semiconductor chip 20 including a capacitor (capacitor portion) 201A is provided on the connector 60. This semiconductor chip 20 is provided above the transistor chip 10 in the Z direction. The semiconductor chip 20 includes a silicon substrate 200. The capacitor 201A is formed using the silicon substrate 200. For example, the silicon substrate 200 functions as one electrode of the capacitor 201A. The thickness of the semiconductor chip 20 in the Z direction is, for example, not less than 10 μm and not more than 250 μm. In the description below, the capacitor 201A formed of the silicon substrate 200 will be referred to as an Si capacitor (or an Si condenser) 201A.

The Si capacitor 201A has a structure in which a dielectric film is sandwiched between one electrode formed by a silicon substrate and the other electrode. For example, in the Si capacitor 201A, the opposing area between two opposing electrodes is increased by a trench formed in the silicon substrate 200. The trench in the silicon substrate 200 of the Si capacitor 201A is formed by etching the silicon substrate 200 by a technique such as RIE (reactive ion etching) or MAC (metal-assisted chemical) etching using a noble metal catalyst.

For example, a resistor (resistive portion) 202 is provided in the silicon substrate 200 (or on the silicon substrate 20) along with the Si capacitor 201A. The resistor 202 is formed using a semiconductor such as polysilicon and/or a metal (or conductive compound) including copper (Cu), aluminum (Al), titanium (Ti), molybdenum (Mo) or tungsten (W). For example, the resistor 202 includes one or more of a thin-film resistor, an interconnect resistor, a silicon resistor, and a via resistor.

In the case where the capacitor 201A and the resistor 202 are provided in a single semiconductor chip 20, the single semiconductor chip 20 functions as a snubber circuit SNB.

In the description below, the semiconductor chip 20 including electronic components (e.g., passive elements) such as a capacitor 201A and a resistor 202 will be referred to as a component chip 20 or a snubber chip 20.

The component chip 20 includes two electrodes 204 and 205. The electrode 204 is one terminal of the current path of the snubber circuit SNB. The electrode 205 is the other terminal of the current path of the snubber circuit SNB. The electrode 204 is provided within the surface of the silicon substrate 200. The electrode 204 is electrically coupled to the lead terminal 401 via a bonding wire 65. The bonding wire 65 is for example a gold (Au) wire or a copper (Cu) wire. The electrode 205 is provided within the back surface of the silicon substrate 200. The electrode 205 is electrically coupled to the connector 60 via a conductor 85 such as solder or conductive paste. The electrode 205 is electrically coupled to the electrode 102 of the transistor chip 10 and the lead terminal 402 via the connector 60. Between the two electrodes 204 and 205, the Si capacitor 201A is coupled in series with the resistor 202. For example, one end of the Si capacitor 201A is electrically coupled to the electrode 204. The other end of the Si capacitor 201A is electrically coupled to one end of the resistor 202. The other end of the resistor 202 is coupled to the electrode 205. However, the manner in which the Si capacitor 201A and the resistor 202 are coupled to the electrodes 204 and 205 may be changed in accordance with the circuit configuration of the snubber circuit SNB.

For example, the capacitance (capacitance value) of the Si capacitor 201A is not less than 1.0nF and not more than 10.0 nF. The resistance value of the resistor 202 is not less than 1.0 Ω and not more than 10.0 Ω. The capacitance of the Si capacitor 201A may be not less than 0.1 nF and not more than 20.0 nF. The resistance value of resistor 202 may be not less than 0.1 Ω and not more than 10.0 Ω.

The resistor 202 may be provided in a semiconductor chip different from the component chip 20. In this case, two semiconductor chips for the snubber circuit SNB are provided above the transistor chip 10 via the connector 60.

A sealing member (packaging material) 90 is provided on the lead frame 40 in such a manner as to cover the two stacked chips 10 and 20 and connectors 60 and 62. The sealing member 90 is an insulator such as epoxy resin. Thus, the two chips 10 and 20 sealed in the single package (sealing member 90) are provided as a single semiconductor device 1. The insulator 409 may be made of the same material as the sealing member 90. In this case, the insulator 409 is continuous with the sealing member 90.

As shown in FIGS. 2 to 5, within the sealing member 90, the semiconductor chip 20 including the capacitor 201A and the resistor 202 is stacked on the semiconductor chip 10 including the transistor TR. The capacitor 201A and resistor 202 of the semiconductor chip 20 are coupled in parallel with the current path of the transistor chip 10. The semiconductor chip 20 functioning as a snubber circuit SNB suppresses surge voltages during the operation of the transistor TR.

### Manufacturing Method

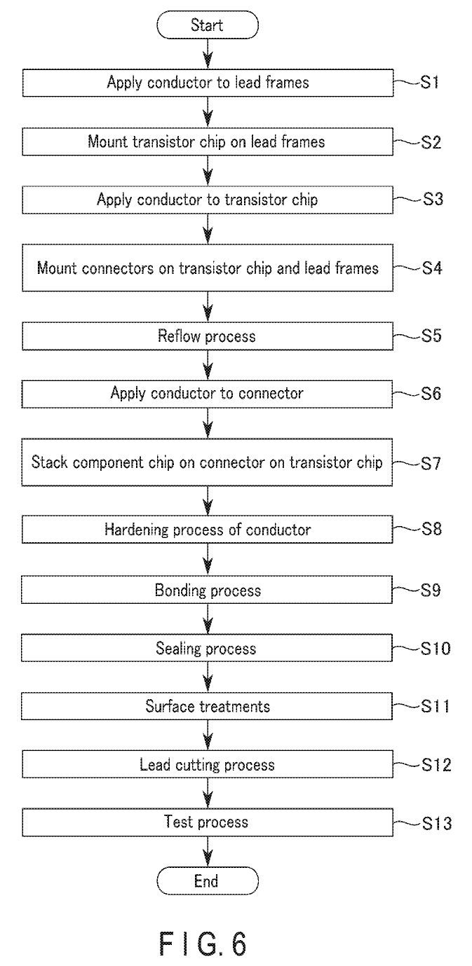

A manufacturing method of the semiconductor device 1 of the present embodiment will be described with reference to FIG. 6. In addition to FIG. 6, FIGS. 2 to 5 will also be referenced as appropriate to describe the manufacturing method of the semiconductor device 1 of the present embodiment.

FIG. 6 is a flowchart for describing the manufacturing method of the semiconductor device 1 of the present embodiment.

As shown in FIG. 6, in step S1, a conductor 80 such as solder is applied to each of a plurality of lead frames 40 provided in a metal plate.

In step S2, the transistor chip 10 is mounted on the lead frames 40 with the applied conductor 80 interposed therebetween.

In step S3, conductors 81A and 81B such as solder are applied to the surface of the transistor chip 10 and the lead frames 40.

In step S4, connectors 60 and 62 are mounted on the transistor chip 10 and the lead frames 40.

In step S5, a reflow process is performed on the transistor chip 10 and the lead frames 40. Thus, the transistor chip 10, the lead frames 40 and the connectors 60 and 62 are coupled (joined) to each other via the molten conductors 80, 81A and 81B.

In step S6, a conductor (conductive paste) 85, such as silver (Ag) paste, is applied to the connector 60. In the case where the conductive paste is used for the conductor 85, the conductor 85 of the conductive paste dries (solidifies) at a temperature lower than that of the reflow process.

In step S7, a component chip 20, including an Si capacitor 201A and a resistor 202, is mounted on the conductor 85 applied to the connector 60. The component chip 20 is stacked on the transistor chip 10 via the connector 60 and the conductor 85. During the manufacturing process of the component chip 20, a trench is formed in the silicon substrate 200 of the Si capacitor 201A by RIE or by MAC etching using a precious metal.

The conductor 85 may be a material such as solder, whose melting point is equal to or lower than that of the conductor 80 applied to the lead frames 40 and that of the conductors 81A and 81B applied to the transistor chip 10. In this case, the component chip 20 is placed on the conductor 85 applied to the connector 60, prior to the reflow process of step S5. A collective reflow process is performed on the conductor 85 and the conductors 80, 81A and 81B. Thus, the transistor chip 10, the lead frames 40 and the connectors 60 and 62 are joined, and the component chip 20 is further joined to the connector 60 via the conductor 85 that is melted during the reflow process.

In step S8, the hardening process of the paste-like conductor 85 is performed. Thus, the component chip 20 is joined to the connector 60. The component chip 20 is electrically coupled to the transistor chip 10 via a conductive paste 85 and the connector 60.

In step S9, a bonding process is performed on the component chip 20. The component chip 20 is coupled to the lead terminals 401 of the lead frames 40 via bonding wires 65.

In step S10, a sealing process is performed on the chips 10 and 20 and the lead frames 40, after a nitrogen plasma cleaning process. Thus, the two chips 10 and 20 on the lead frames 40 are sealed in the sealing member 90.

In step S11, surface treatments such as burr removal, exterior plating and marking are performed on the sealing member 90 covering the chips 10 and 20 and the lead frames 40.

In step S12, a lead cutting process is performed on the metal plate including the plurality of lead frames 40. As a result, the plurality of semiconductor devices 1 are cut out from the metal plate.

In step S13, a test process is performed on each of the semiconductor devices 1. In the test process, the electrical characteristics of the semiconductor devices 1 are measured, and visual defects of the semiconductor devices 1 are inspected.

Through the above manufacturing process, the semiconductor devices 1 of the present embodiment is completed.

### Characteristics

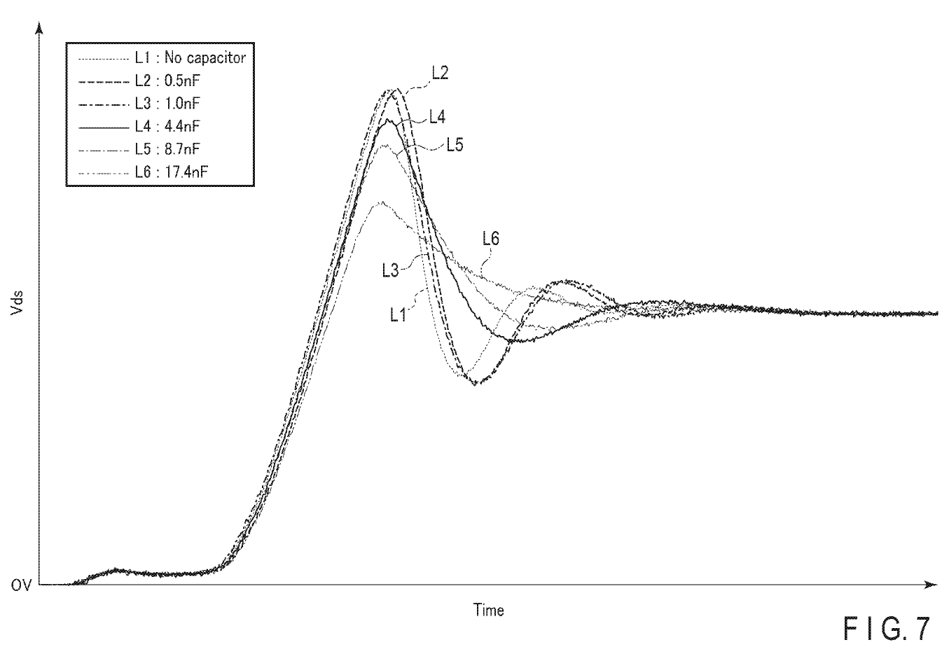

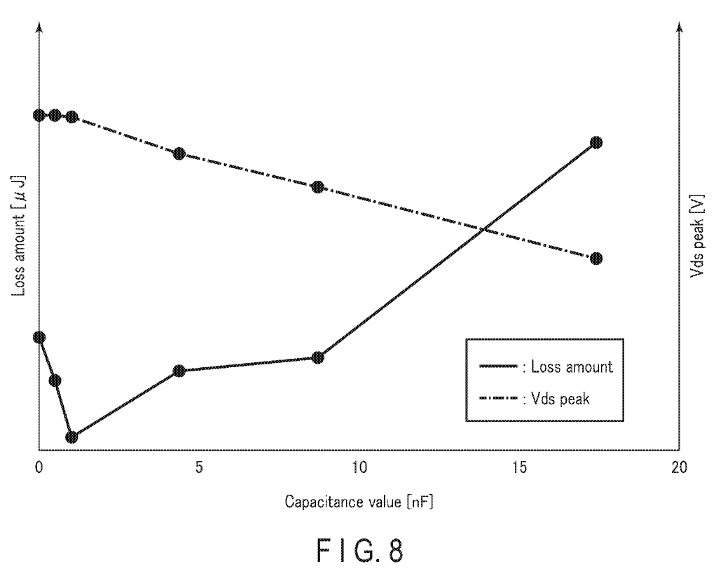

The characteristics of the semiconductor device 1 of the present embodiment will be described with reference to FIGS. 7 and 8.

FIG. 7 is a graph showing the drain-source voltage characteristics of the semiconductor device 1 of the present embodiment when the transistor TR is turned off. In FIG. 7, the horizontal axis of the graph corresponds to time, and the vertical axis of the graph corresponds to the drain-source voltage (Vds).

The capacitances (capacitance values) of the Si capacitors 201A are set to 0.5nF, 1.0nF, 4.4nF, 8.7nF, and 17.4nF. FIG. 7 also shows an example in which the Si capacitor 201A is not provided in the semiconductor device. The resistance value of the resistor 202 is set to 1.0Ω.

Line L1 in FIG. 7 indicates the characteristics of the semiconductor device in which no Si capacitor is provided. Line L2 in FIG. 7 indicates the characteristics of the semiconductor device 1 in the case where the capacitance of the Si capacitor 201A is 0.5nF. Line L3 in FIG. 7 indicates the characteristics of the semiconductor device 1 in the case where the capacitance of the Si capacitor 201A is 1.0nF. Line L4 in FIG. 7 indicates the characteristics of the semiconductor device 1 in the case where the capacitance of the Si capacitor 201A is 4.4nF. Line L5 in FIG. 7 indicates the characteristics of the semiconductor device 1 in the case where the capacitance of the Si capacitor 201A is 8.7nF. Line L6 in FIG. 7 indicates the characteristics of the semiconductor device 1 in the case where the capacitance of the Si capacitor 201A is 17.4nF.

As shown in FIG. 7, when the transistor TR is turned off, the voltage Vds includes a peak due caused by a surge voltage.

In the case where the Si capacitor 201A has a capacitance of 4.4nF or more, the peak of the voltage Vds is reduced compared to the case where the capacitance of Si capacitor 201A is less than 1.0nF.

Furthermore, as the capacitance of Si capacitor 201A increases, the ringing phenomenon of the voltage Vds at the transistor TR is suppressed.

In this manner, the semiconductor device 1 according to the present embodiment can suppress large surge voltages and ringing.

FIG. 8 is a graph illustrating characteristics with respect to the changes of the loss amount and the drain-source voltage to the capacitance of the Si capacitor 201A of the semiconductor device 1 of the present embodiment. In FIG. 8, the horizontal axis of the graph corresponds to the capacitance value of the Si capacitor 201A, one vertical axis of the graph corresponds to the turn-off loss amount of the transistor TR, and the other vertical axis corresponds to the peak value of the drain-source voltage. In this example, the turn-off loss amount of the transistor TR is defined as the loss (Vds × Id) occurring during the period from the time when the drain-source voltage reaches its peak value until the ringing phenomenon subsides. The resistance value of resistor 202 is set to 1.0Ω.

As shown in FIG. 8, as the capacitance value of the Si capacitor 201A increases, the peak value of the source voltage decreases. In other words, the semiconductor device 1 of the present embodiment can suppress surge voltages when the semiconductor device 1 (the transistor TR) is turned off.

With regard to losses in the semiconductor device 1 during turn-off, as the capacitance of the Si capacitor 201A increases, the duration until the ringing phenomenon subsides and transistor TR turns off becomes longer. In this case, the longer turn-off period increases the amount of loss during turn-off.

In the case where the capacitance value of the Si capacitor 201A is not less than 1.0nF and not more than 10.0 nF, the turn-off period of the semiconductor device 1 is controlled to a more appropriate value. As a result, the semiconductor device 1 of the present embodiment can achieve low turn-off losses.

Note that in the case where the capacitance value of the Si capacitor 201A is not less than 1.0nF and not more than 10.0 nF, the semiconductor device 1 of the present embodiment can achieve substantially the same advantages as long as the resistance value of the resistor 202 is in the range of 1.0Ω to 10.0Ω.

In the case where the Si capacitor 201A and the resistor 202 are incorporated within the same sealing member 90 as the transistor TR, as in the present embodiment, the semiconductor device 1 of the present embodiment can reduce surge voltages and turn-off loss amount compared to the case where the Si capacitor and resistor are provided outside the transistor package.

By incorporating components including the Si capacitor 201A and the resistor 202 within the same package as the transistor TR, as in the semiconductor device 1 of the present embodiment, the wiring length between the transistor TR and the components 201A and 202 is shortened. Therefore, the parasitic inductance between the transistor TR and the components 201A and 202 is reduced.

As a result, the semiconductor device 1 of the present embodiment can reduce turn-off loss of the transistor TR.

For example, as the switching operation of the transistor TR becomes faster, the effect of suppressing the adverse influence of parasitic inductance becomes more significant.

### Summary

In semiconductor devices that control current, spike-like voltage overshoots may occur during switching operations of transistors (e.g., MOSFETs), particularly when turning off. These spike-like voltage overshoots are referred to as surge voltages.

When selecting transistors for use in power devices, it is advisable to ensure that surge voltages do not exceed the maximum ratings of the transistors.

In general, however, MOSFETs having a high breakdown voltage exhibit a high on-resistance (Ron). This high on-resistance has been a cause of losses during the switching operations of the MOSFETs.

Snubber circuits are known as circuits for suppressing surge voltages. Snubber circuits include a C snubber circuit, an RC snubber circuit, a charge-discharge RCD snubber circuit, and a discharge-prevention RCD snubber circuit. The C snubber circuit is a circuit that includes capacitance element (C) coupled in parallel with a MOSFET between the drain and source terminals of the MOSFET. The RC snubber circuit is a circuit that uses a resistive element (R) and a capacitive element. The charge-discharge and discharge-prevention RCD snubber circuits are circuits that use a diode (D). These snubber circuits are coupled between the drain and source terminals of the MOSFET. Thus, the snubber circuits absorb and suppress surge voltages when the MOSFET is turned off.

In the case where RC snubber circuits are mounted on a wiring board, one RC snubber circuit is provided for each MOSFET. In the case where long wiring is used to couple the MOSFET and RC snubber circuit to each other, the wiring contains parasitic inductance. This parasitic inductance in the wiring may cause noise during the switching operations of the MOSFET.

For example, technologies have been proposed in which resistive elements and capacitive elements are embedded within the MOSFET semiconductor chip, or in which chip components of resistive elements and capacitive elements are embedded within the MOSFET package.

In a structure in which resistive elements and capacitive elements are embedded within a semiconductor chip, the areas of the resistive elements and capacitive elements are large, and the area of the MOSFET (switching element) in the semiconductor chip is relatively small. Therefore, the structure in which the resistive and capacitive elements are embedded within the semiconductor chip may lead to issues with operating efficiency per unit chip area and with cost.

In a structure in which chip components are embedded in a package, the large size of the chip components may cause problems related to the size of the semiconductor package and the reliability of the chip components.

The semiconductor device 1 of the present embodiment includes, within the sealing member 90, a transistor chip 10 and a component chip 20 including an Si capacitor 201A and a resistor 202. The component chip 20 is stacked above the transistor chip 10 via a connector 60. The Si capacitor 201A and resistor 202 of the component chip 20 are coupled in parallel with the current path of the transistor TR of the transistor chip 10. The component chip 20 functions as a snubber circuit SNB.

Thus, the semiconductor device 1 of the present embodiment can reduce the peak value of the surge voltage generated when the transistor TR is turned off. Furthermore, the semiconductor device 1 of the present embodiment can suppress the ringing phenomenon of the transistor TR during turn-off.

In the present embodiment, a transistor TR having a low on-resistance and a low breakdown voltage can be selected for the semiconductor device 1 in accordance with a reduction in surge voltage.

In the semiconductor device 1 of the present embodiment, an Si capacitor 201A is used in the snubber circuit SNB.

In general, the performance of multilayer ceramic capacitors (MLCCs) is unstable under high-temperature conditions. Therefore, from the perspective of semiconductor device performance stability, it is difficult to integrate a multilayer ceramic capacitor into the same package as a power device that operates at relatively high temperatures.

The Si capacitor 201A has high heat resistance and stable performance even under high-temperature conditions. Therefore, the Si capacitor 201A can operate in a stable manner with almost no change in capacitance attributed to heat generation by the transistor TR.

In the semiconductor device 1 of the present embodiment, the Si capacitor 201A is used as the capacitive element of the snubber circuit SNB, and the snubber circuit SNB can be integrated within the same sealing member 90 as the transistor TR.

Thus, the semiconductor device 1 of the present embodiment can reduce the wiring length between the components 201A and 202 of the snubber circuit SNB and the transistor TR. Therefore, the semiconductor device 1 of the present embodiment can reduce the parasitic inductance in the wiring between the components 201A and 202 and the transistor TR. Therefore, the semiconductor device 1 of the present embodiment can reduce loss when the semiconductor device 1 is turned off.

Furthermore, by using the Si capacitor 201A, the semiconductor device 1 of the present embodiment can achieve noise performance in which the adverse effect of the operating temperature of the transistor TR on the capacitive element of the snubber circuit SNB is suppressed. As a result, the semiconductor device 1 of the present embodiment can improve switching efficiency.

In the semiconductor device 1 of the present embodiment, the snubber circuit SNB is stacked on the transistor TR within the single sealing member 90. Thus, the semiconductor device 1 of the present embodiment enables a reduction in the package substrate area. Consequently, the semiconductor device 1 of the present embodiment enables a reduction in the package size.

In the case where the semiconductor device 1 of the present embodiment is applied to a power module, the number of components on the wiring substrate can be reduced by providing components 201A and 202 of the snubber circuit SNB in the same package as the transistor TR.

By reducing the size of the semiconductor device and decreasing the number of components on the wiring substrate, the semiconductor device 1 of the present embodiment, as well as a power module including the semiconductor device 1, can achieve low manufacturing costs.

In the present embodiment, a connector 60 made of copper is provided between the transistor chip 10 and the component chip 20. The connector 60 improves the heat dissipation performance of the transistor chip 10 and the component chip 20. Thus, the semiconductor device 1 of the present embodiment can further stabilize the operations of the transistor TR and snubber circuit SNB.

As described above, the semiconductor device 1 of the present embodiment can improve the characteristics of the semiconductor device.

### Second Embodiment

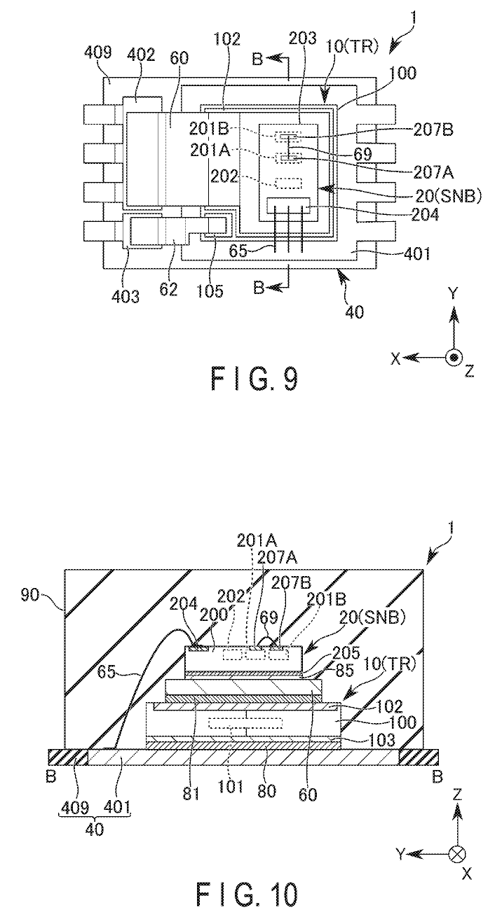

A semiconductor device according to the second embodiment will be described with reference to FIGS. 9 to 11.

FIG. 9 is a top view showing an example of the planar structure of the semiconductor device 1 of the present embodiment. FIG. 10 is a cross-sectional view taken along line B-B in FIG. 9 and shows an example of the cross-sectional structure of the semiconductor device 1 of the present embodiment.

As shown in FIGS. 9 and 10, a plurality of Si capacitors 201A and 201B may be provided within a single semiconductor chip (component chip) 20.

The component chip 20 includes, for example, two Si capacitors 201A and 201B. Of the two Si capacitors 201A and 201B, the Si capacitor 201B is an optional component used selectively.

One terminal of the Si capacitor 201A is coupled to a resistor 202 and to an electrode 207A on the front surface of the component chip 20.

In the case where the Si capacitor 201B is used, for example, the Si capacitor 201B is electrically coupled to the Si capacitor 201A via a bonding wire 69. One terminal of the Si capacitor 201B is coupled to an electrode 207B on the front surface of the component chip 20. The other terminal of the Si capacitor 201B is coupled to an electrode 205 on the back surface of component chip 20. The electrode 207B is coupled to the electrode 207A by the bonding wire 69. Thus, the Si capacitor 201B is electrically coupled to the Si capacitor 201A.

In the case where the Si capacitor 201B is not used, the electrode 207B is not coupled to the electrode 207A. This electrically isolates the Si capacitor 201B from the current path of the snubber circuit SNB.

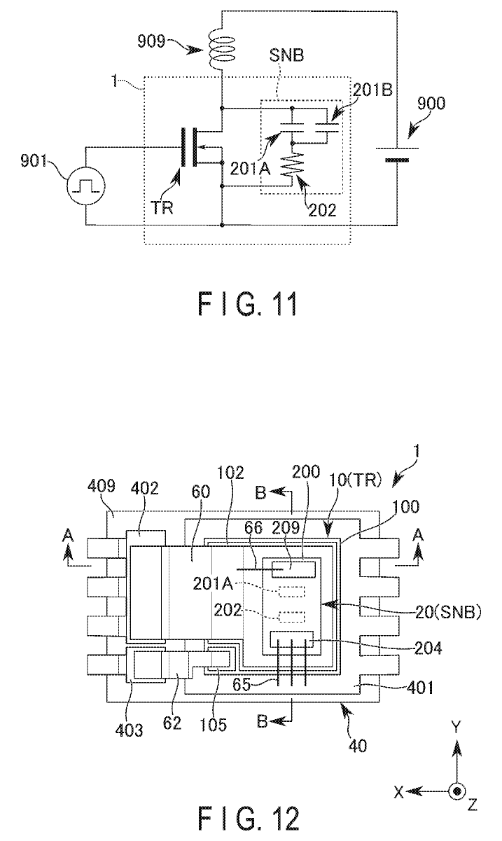

FIG. 11 is a circuit diagram showing the circuit configuration of semiconductor device 1 of the present embodiment when the optional Si capacitor 201B is used.

As shown in FIG. 11, in the case where the Si capacitor 201B is used, the Si capacitor 201B is coupled in parallel with the Si capacitor 201A.

In this way, in the case where the Si capacitor 201B is used in accordance with the electrical characteristics of the snubber circuit SNB, the capacitance of the snubber circuit SNB can be adjusted.

Note that a plurality of resistors 202 may be provided within the single component chip 20.

As described above, the semiconductor device 1 of the present embodiment can improve the characteristics of the semiconductor device.

### Third Embodiment

A semiconductor device according to the third embodiment will be described with reference to FIGS. 12 to 14.

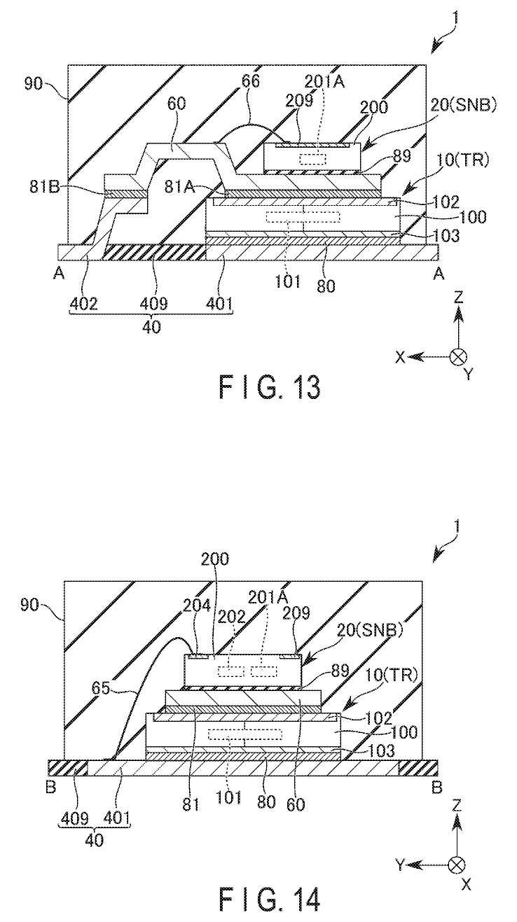

FIG. 12 is a top view showing an example of the planar structure of the semiconductor device according to the present embodiment. FIG. 13 is a cross-sectional view taken along line A-A in FIG. 12 and shows an example of the cross-sectional structure of the semiconductor device of the present embodiment. FIG. 14 is a cross-sectional view taken along line B-B in FIG. 12 and shows an example of the cross-sectional structure of the semiconductor device of the present embodiment.

As shown in FIGS. 12 to 14, terminals of an Si capacitors 201A of a component chip 20 may be electrically coupled to corresponding lead terminals 402 on a lead frame 40 by bonding wires 66.

In the present embodiment, the component chip 20 does not have electrodes on its back surfaces. An insulator 89, such as an adhesive, is provided between the back surface of the component chip 20 and a connector 60. The component chip 20 is fixed onto the connector 60 by an insulator 89.

The component chip 20 includes two electrodes 204 and 209 provided on the front surface of the component chip 20. An Si capacitor 201A and a resistor 202 are coupled in series between the electrodes 204 and 209.

The electrode 209 is coupled to the other terminal of the Si capacitor 201A via the resistor 202. The electrode 209 is electrically coupled to the connector 60 via a bonding wire 66. Thus, the other terminal of the Si capacitor 201A is electrically coupled to an electrode 102 and the lead terminal 402 of the transistor TR.

As described above, in the present embodiment, the Si capacitor 201A and resistor 202 that form a snubber circuit SNB are coupled in parallel with the current path of the transistor TR via bonding wires 65 and 69.

Even where the coupling between the Si capacitor 201A and the lead frames 40 is achieved by the bonding wire 65, as in the present embodiment, the semiconductor device 1 can reduce surge voltage and suppress ringing in substantially the same manner as in the first embodiment.

Therefore, the semiconductor device 1 of the present embodiment can improve the characteristics of the semiconductor device.

### Fourth Embodiment

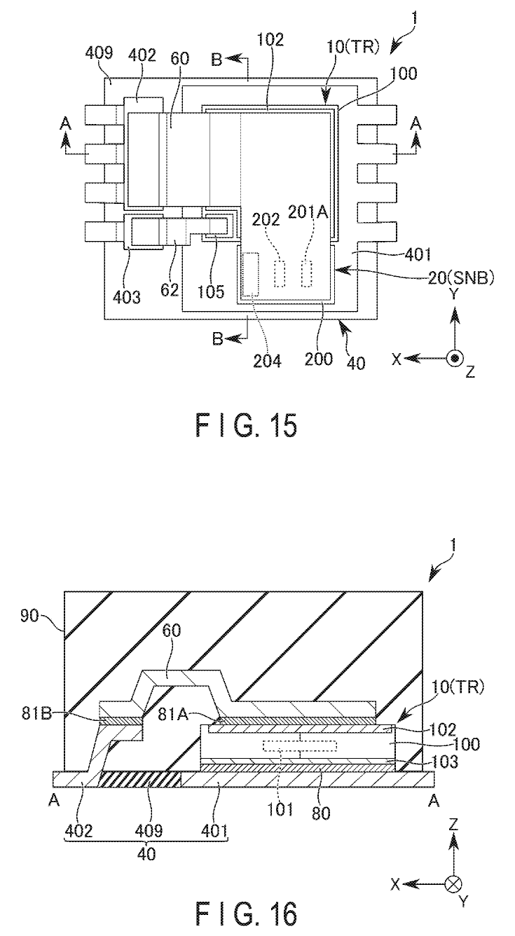

A semiconductor device according to the fourth embodiment will be described with reference to FIGS. 15 to 17.

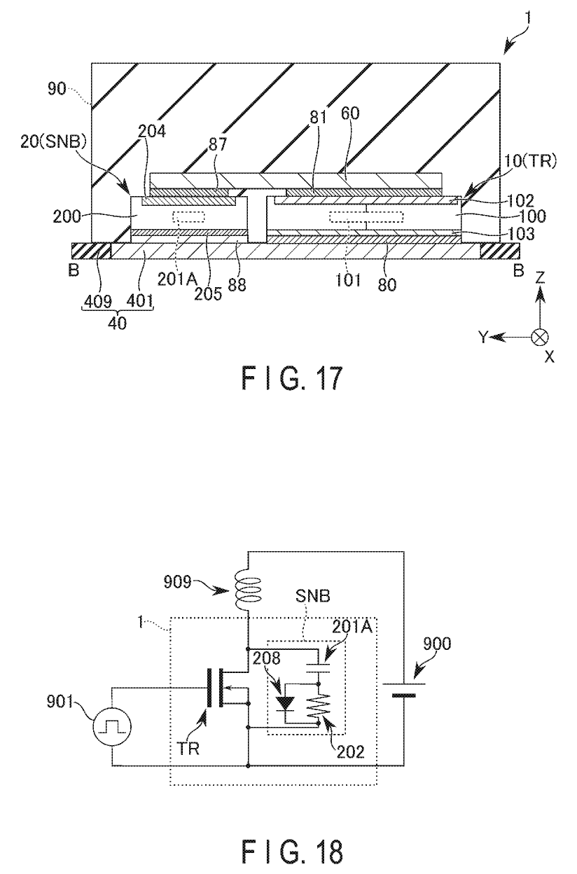

FIG. 15 is a top view showing an example of the planar structure of the semiconductor device 1 of the present embodiment. FIG. 16 is a cross-sectional view taken along line A-A in FIG. 15 and shows an example of the cross-sectional structure of the semiconductor device 1 of the present embodiment. FIG. 17 is a cross-sectional view taken along line B-B in FIG. 15 and shows an example of the cross-sectional structure of the semiconductor device 1 of the present embodiment.

As shown in FIGS. 15 to 17, in the semiconductor device 1 of the present embodiment, a component chip 20 including an Si capacitor 201A is provided on a lead frame 40. On the lead frame 40, the component chip 20 is adjacent to a transistor chip 10 in a direction parallel to the surface of the lead frame 40 (in this example, the Y direction).

On the lead frame 40, the transistor chip 10 and the component chip 20 are covered by a sealing member 90.

The component chip 20 is provided between a connector 60 and a lead terminal 401 in the Z direction.

An electrode 204 on the front surface of the component chip 20 is electrically coupled to the connector 60 via a conductor 87. The electrode 204 is electrically coupled to a lead terminal 402 via the connector 60. An electrode 205 on the back surface of the component chip 20 is electrically coupled to the lead terminal 401 via a conductor 88. Thus, a snubber circuit SNB is coupled in parallel with the current path of a transistor TR. The conductors 87 and 88 are, for example, solder or conductive paste.

The electrode 204 may be electrically coupled to the lead terminal 402 by a bonding wire, without using the connector 60.

The connector 60 includes a flat portion extending from the transistor chip 10 to the component chip 20 in the Y direction. The flat portion of the connector 60 covers an electrode 102 and the electrode 204. The connector 60 does not have to extend on the front surface of the component chip 20. In this case, the component chip 20 is provided on the lead terminal 401 without being sandwiched between the connector 60 and the lead terminal 401. The electrode 204 of the component chip 20 is electrically coupled to the lead terminal 402 via a bonding wire.

The transistor chip 10 and the component chip 20 may be laid out on the lead frame 40 such that the component chip 20 is adjacent to the transistor chip 10 in the X direction.

Even if the semiconductor device 1 has a structure in which the transistor chip 10 and the component chip 20 are adjacent to each other in the Y direction (or X direction) on the lead frame 40, as in the present embodiment, the semiconductor device 1 of the present embodiment can achieve substantially the same advantages as the above-described embodiments.

The semiconductor device 1 of the present embodiment has a structure in which the component chip 20 including the Si capacitor 201A and a resistor 202 is sandwiched between two metal plates (e.g., copper plates) 60 and 401. This structure allows heat generated by the component chip 20, which serves as the snubber circuit SNB, to be dissipated through the metal plates 60 and 401.

As a result, the semiconductor device 1 of the present embodiment can mitigate the adverse effects of heat generated during the operation of the semiconductor device 1.

Therefore, the semiconductor device 1 of the present embodiment can improve the characteristics of the semiconductor device.

### Fifth Embodiment

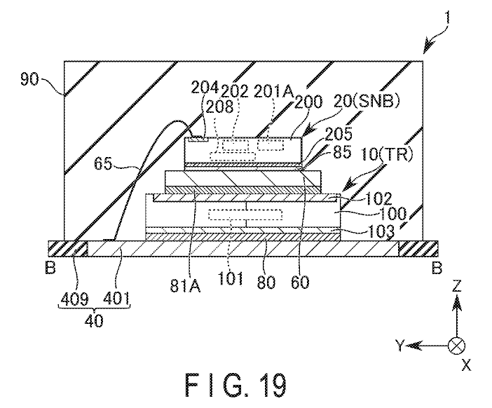

A semiconductor device according to the fifth embodiment will be described with reference to FIGS. 18 and 19.

FIG. 18 is a circuit diagram showing the circuit configuration of the semiconductor device 1 of the present embodiment.

As shown in FIG. 18, in the semiconductor device 1 of the present embodiment, the snubber circuit SNB may be an RCD snubber circuit. The snubber circuit SNB includes a diode 208 in addition to the Si capacitor 201A and the resistor 202.

The diode 208 is coupled in parallel with the resistor 202. One end (e.g., an anode) of the diode 208 is coupled to one end of the resistor 202 (and to the other end of the Si capacitor 201). The other end (e.g., a cathode) of the diode 208 is coupled to the other end of the resistor 202 (and to the other end of the current path of a transistor TR). For example, the diode 208 is a PN junction diode.

FIG. 19 is a cross-sectional view showing an example of the cross-sectional structure of the semiconductor device 1 of the present embodiment.

As shown in FIG. 19, the diode 208 is provided within a component chip 20 together with the Si capacitor 201A and the resistor 202. The diode 208 is provided, for example, on the back surface side of the silicon substrate 200 of the component chip 20.

For example, one end of the diode 208 is coupled to one end of the resistor 202 via a component (not shown) provided within the component chip 20. For example, the other end of the diode 208 is electrically coupled to a connector 60 via an electrode 205 and a conductor 85. In this case, the other end of the resistor 202 is electrically coupled to the connector 60 via, for example, an additional electrode (not shown) and a bonding wire (not shown). Note that the other end of the resistor 202 may be coupled to the other end of the diode 208 (or electrode 205) via a component (not shown) provided within the component chip 20.

In this manner, the diode 208 is coupled in parallel with the resistor 202 within the component chip 20.

The diode 208 may be provided in a semiconductor chip different from the component chip 20.

As described above, the semiconductor device 1 of the present embodiment includes the component chip 20 of the RCD snubber circuit. This allows the semiconductor device 1 of the present embodiment to suppress surge voltages that may occur during the switching operation of the transistor TR.

Therefore, the semiconductor device 1 of the present embodiment can improve the characteristics of the semiconductor device.

### Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a package substrate including a first lead terminal and a second lead terminal;
a first semiconductor chip provided on the first lead terminal and including a switching element;
a connector extending from a front surface of the first semiconductor chip to the second lead terminal; and
a second semiconductor chip provided on the connector above the first semiconductor chip and including a resistor portion and a first capacitor portion provided in a semiconductor substrate,
wherein
the first semiconductor chip includes a first electrode provided on the front surface of the first semiconductor chip and a second electrode provided on a back surface of the first semiconductor chip,
the second semiconductor chip includes a third electrode and a fourth electrode,
the first electrode is electrically coupled to the second lead terminal,
the second electrode is electrically coupled to the first lead terminal,
the third electrode is electrically coupled to the first lead terminal, and
the fourth electrode is electrically coupled to the second lead terminal.

2. The semiconductor device according to claim 1, wherein
the semiconductor substrate is a silicon substrate, and
the first capacitor portion is a silicon capacitor.

3. The semiconductor device according to claim 1, wherein
the first capacitor portion is coupled in series with the resistor portion, and
the first capacitor portion and the resistor portion, which are coupled in series, are coupled in parallel with a current path of the switching element between the first electrode and the second electrode.

4. The semiconductor device according to claim 1, wherein
the second semiconductor chip further includes a second capacitor portion provided in the semiconductor substrate, and
the second capacitor portion is electrically coupled to the first capacitor portion via a first wire.

5. The semiconductor device according to claim 1, wherein
the third electrode is provided on a surface of the second semiconductor chip,
the fourth electrode is provided on a back surface of the second semiconductor chip,
the first electrode is electrically coupled to the second lead terminal via the connector,
the second electrode is electrically coupled to the first lead terminal via a conductor provided between the back surface of the first semiconductor chip and the first lead terminal,
the third electrode is electrically coupled to the first lead terminal via a second wire, and
the fourth electrode is electrically coupled to the first electrode and the second lead terminal via the connector.

6. The semiconductor device according to claim 1, wherein
the third electrode and the fourth electrode are provided on a front surface of the second semiconductor chip,
the first electrode is electrically coupled to the second lead terminal via the connector,
the second electrode is electrically coupled to the first lead terminal via a conductor provided between the back surface of the first semiconductor chip and the first lead terminal,
the third electrode is electrically coupled to the first lead terminal via a third wire, and
the fourth electrode is electrically coupled to the connector via a fourth wire.

7. The semiconductor device according to claim 1, wherein
a capacitance of the first capacitor portion is not less than 0.1 nF and not more than 20.0 nF.

8. The semiconductor device according to claim 7, wherein
a resistance value of the resistor portion is not less than 0.1 Ω and not more than 10.0 Ω.

9. The semiconductor device according to claim 7, wherein
the switching element includes a transistor, and
the transistor operates using a voltage of not less than 6V and not more than 300V.

10. The semiconductor device according to claim 1, wherein
each of the first lead terminal, the second lead terminal and the connector include copper.

11. The semiconductor device according to claim 1, further comprising:
a sealing member provided on the package substrate and covering the first semiconductor chip and the second semiconductor chip.

12. The semiconductor device according to claim 1, wherein
the second semiconductor chip further includes a diode coupled in parallel with the resistor portion.

13. The semiconductor device according to claim 1, wherein
the connector includes a first portion located on the front surface of the first semiconductor chip, a second portion located on the second lead terminal, and a third portion located between the first portion and the second portion, and
the third portion is positioned higher than the first and second portions in a first direction perpendicular to a surface of the package substrate.

14. The semiconductor device according to claim 13, wherein
the second lead terminal includes a fourth portion located on an edge of the package substrate, a fifth portion coupled to the second portion, and a sixth portion located between the fourth portion and the fifth portion,
the fifth portion is positioned higher than the fourth portion in the first direction, and
the sixth portion is inclined relative to the surface of the package substrate.

15. A semiconductor device comprising:
a package substrate including a first lead terminal and a second lead terminal;
a connector provided above the package substrate;
a first semiconductor chip provided between the first lead terminal and the connector and including a switching element; and
a second semiconductor chip including a resistor portion and a first capacitor provided in a semiconductor substrate, being adjacent to the first semiconductor chip, and located between the first lead terminal and the connector,
wherein
the first semiconductor chip includes a first electrode provided on a surface of the first semiconductor chip and a second electrode provided on a back surface of the first semiconductor chip,
the second semiconductor chip includes a third electrode and a fourth electrode,
the first electrode is electrically coupled to the second lead terminal via the connector,
the second electrode is electrically coupled to the first lead terminal,
the third electrode is electrically coupled to the second lead terminal via the connector, and
the fourth electrode is electrically coupled to the first lead terminal.

16. The semiconductor device according to claim 15, wherein
the semiconductor substrate is a silicon substrate, and
the first capacitor portion is a silicon capacitor.

17. The semiconductor device according to claim 15, wherein
the connector includes a flat portion extending from the first semiconductor chip to the second semiconductor chip and covering the first and third electrodes.

18. The semiconductor device according to claim 15, wherein
the second semiconductor chip is adjacent to the first semiconductor chip in a direction parallel to a surface of the package substrate.

19. The semiconductor device according to claim 15, wherein
a capacitance of the first capacitor portion is not less than 0.1nF and not more than 20.0 nF.

20. The semiconductor device according to claim 19, wherein
a resistance value of the resistor portion is not less than 0.1 Ω and not more than 10.0 Ω.
